(19) United States
(12) Patent Application Publication
(10) Pub. No.: US 2013/0168689 A1
(43) Pub. Date: Jul. 4, 2013

(54) NITRIDE BASED SEMICONDUCTOR DEVICE AND MANUFACTURING METHOD THEREOF

(71) Applicant: SAMSUNG ELECTRONICS CO., LTD., Suwon-si (KR)

(72) Inventor: Jae Hoon LEE, Suwon-si (KR)

(73) Assignee: SAMSUNG ELECTRONICS CO., LTD., Suwon-si (KR)

(21) Appl. No.: 13/731,981

(22) Filed: Dec. 31, 2012

(30) Foreign Application Priority Data
Dec. 30, 2011 (KR) 10-2011-0147130

(51) Int. Cl. H01L 29/267; H01L 21/02

(52) U.S. Cl. CPC H01L 29/267; H01L 21/0262
USPC 257/76; 438/478

(57) ABSTRACT

With the formation of a SiₓC₁₋ₓN functional layer on a barrier layer, a nitride based semiconductor device may improve a surface roughness of the barrier layer, and may reduce a surface leakage current by, for example, inhibiting aluminum (Al) and oxygen (O) from combining with each other on the barrier layer. In addition, when compared to a structure in which a barrier layer and an electrode directly contact each other, a barrier may be relatively low in a structure in which the SiₓC₁₋ₓN functional layer is formed between the barrier layer and the electrode. Accordingly, an operating voltage may be lowered to increase a current density.

### CROSS-REFERENCE TO RELATED APPLICATION

This application claims the benefit of Korean Patent Application No. 10-2011-0147130, filed on Dec. 30, 2011, in the Korean Intellectual Property Office, the disclosure of which is incorporated herein by reference.

### BACKGROUND

1. Field of the Disclosure

The present disclosure relates to a nitride based semiconductor device and a manufacturing method thereof, and more particularly, to a nitride based semiconductor device and a manufacturing method thereof that may improve a surface roughness of a barrier layer and may reduce a surface leakage current by, for example, inhibiting aluminum (Al) and oxygen (O) from combining with each other.

2. Description of the Related Art

As information communication technologies have been considerably developed globally, communication technologies for high-speed and large-capacity signal communication have been rapidly developed. In particular, as demand for a personal cellular phone (PCS), satellite communication, military radar, broadcasting communication, a communication relay, and the like in wireless communication technologies has increased, demand for a power electronic device required for a high-speed information communication system of a microwave band and millimeter-wave band has increased. Consequently, research on high power electronic devices and power consumption is being actively conducted.

Particularly, since a GaN-based nitride semiconductor has advantageous properties, such as a high energy gap, a high heat stability, a high chemical stability, and a high electronic saturation velocity of, for example, about 3×10⁷ centimeters per second (cm/sec), the nitride semiconductor may be readily utilized as a light device, and a high frequency and high power electronic device. Accordingly, research on the nitride semiconductor is being actively conducted all over the world.

An electronic device based on the GaN-based nitride semiconductor may have various advantages such as, for example, a high breakdown field of, for example, about 3×10⁶ volts per centimeter (V/cm), a maximum current density, a stable high temperature operation, a high thermal conductivity, and the like. A heterostructure field effect transistor (HFET) formed from, for example, a heterojunction of aluminum gallium nitride (AlGaN) and gallium nitride (GaN), has a high band-discontinuity at a junction interface, whereby a high-density of electrons may be freed at the interface and thus, an electron mobility may increase. Accordingly, the HFET may be applicable as the high-power device.

At a junction of a metal and a semiconductor, an ohmic electrode having an ohmic characteristic and a Schottky electrode having a Schottky characteristic are important when an AlGaN/GaN HFET and a Schottky Barrier Diode (SBD) are manufactured. The ohmic electrode may refer to an electrode where a current may be transferred freely between an electrode and a semiconductor. The Schottky electrode may have a characteristic in that a current may not flow in a reverse direction. In order to improve characteristics of the AlGaN/GaN HFET and the SBD, electron mobility of a channel layer should be high, an ohmic contact resistance should be low, and a height of a Schottky barrier of the Schottky electrode should be high. However, in a structure of an AlGaN/GaN HFET with high electron mobility, a Schottky junction with a relatively high Schottky barrier height may have a disadvantage in that a leakage current flowing along a surface may decrease a device property since an AlGaN surface is unstable.

### SUMMARY

An aspect of the present disclosure provides a nitride based semiconductor device and a manufacturing method thereof that may improve a surface roughness of a barrier layer, and may reduce a surface leakage current by, for example, inhibiting aluminum (Al) and oxygen (O) from combining with each other.

According to an aspect of the present disclosure, there is provided a nitride based semiconductor device including a substrate, a gallium nitride (GaN) layer formed on the substrate, a barrier layer formed on the GaN layer, the barrier layer having a different band-gap energy than the GaN layer, and a silicon carbon nitride (SiₓC₁₋ₓN) functional layer formed on the barrier layer.

The x in the SiₓC₁₋ₓN functional layer may have a value in a range of 0<x<1.

The SiₓC₁₋ₓN in the SiₓC₁₋ₓN functional layer may correspond to at least one of a single crystal, a poly crystal, and an amorphous SiₓC₁₋ₓN.

The SiₓC₁₋ₓN functional layer may have a thickness ranging from 0.1 nanometers (nm) to 100 nm.

The barrier layer may include at least one layer formed of a material having Formula 1:

Al_{y}In_{z}Ga_{1-y}N, [Formula 1]

where 0.1≦y≦1 and 0≦z≦0.3.

A low temperature GaN layer may be formed on the barrier layer.

The substrate may be formed of one selected from a group consisting of sapphire, silicon (Si), aluminum nitride (AlN), silicon carbide (SiC), and GaN.

The nitride based semiconductor device may be any one of a normally-on device, a normally-off device, and a Schottky barrier diode.

An ohmic electrode in the Schottky barrier diode may be formed of a material selected from a group consisting of chromium (Cr), Al, tantalum (Ta), titanium (Ti), gold (Au), nickel (Ni), and platinum (Pt).

A Schottky electrode in the Schottky barrier diode may be formed of a material selected from a group consisting of Ni, Au, copper indium oxide (CuInO₂), indium tin oxide (ITO), and Pt, and alloys thereof.

According to another aspect of the present disclosure, there is also provided a method of manufacturing a nitride based semiconductor device, the method including forming a GaN layer on a substrate, forming, on the GaN layer, a barrier layer having a different band-gap energy than the GaN layer, and forming a SiₓC₁₋ₓN functional layer on the barrier layer.

Tetrabromomethane (CBr₄) may be used as a source of carbon (C), ditertiarybutyl silane (DTBSI) may be used as a source of Si, and ammonia (NH₃) may be used as a source of nitrogen (N), in the forming of the SiₓC₁₋ₓN functional layer.

The SiₓC₁₋ₓN functional layer may be formed through an in-situ process by metal organic chemical vapor deposition (MOCVD).

The x in the SiₓC₁₋ₓN functional layer may have a value in a range of 0<x<1.

The SiₓC₁₋ₓN in the SiₓC₁₋ₓN functional layer may correspond to at least one of a single crystal, a poly crystal, and an amorphous SiₓC₁₋ₓN.

The SiₓC₁₋ₓN functional layer may have a thickness ranging from 0.1 nm to 100 nm.

The barrier layer may include at least one layer formed of a material having Formula 1:

Al_{y}In_{z}Ga_{1-y}N, [Formula 1]

where 0.1≦y≦1 and 0≦z≦0.3.

According to another aspect of the present disclosure, there is provided a nitride based semiconductor device including a substrate, a nitride semiconductor layer formed on the substrate, a barrier layer formed on the nitride semiconductor layer, the barrier layer having a different band-gap energy than the nitride semiconductor layer, and a silicon carbon nitride (SiₓC₁₋ₓN) functional layer formed on the barrier layer. The x in the SiₓC₁₋ₓN functional layer may have a value in a range of 0≦x≦1.

At least one of a low temperature GaN layer and a p-type nitride semiconductor layer may be formed on the barrier layer.

The SiₓC₁₋ₓN functional layer may be formed on the at least one of a low temperature GaN layer and a p-type nitride semiconductor layer.

The SiₓC₁₋ₓN functional layer may be formed directly on the barrier layer.

### BRIEF DESCRIPTION OF THE DRAWINGS

These and/or other aspects, features, and advantages of the disclosure will become apparent and more readily appreciated from the following description of exemplary embodiments, taken in conjunction with the accompanying drawings of which:

FIG. 1 is a cross-sectional view illustrating a structure of a nitride based semiconductor device according to an embodiment of the present disclosure;

FIG. 2A is a Transmission Electron Microscope (TEM) photograph of a portion of a nitride based semiconductor device according to an embodiment of the present disclosure;

FIG. 2B is a graph illustrating data obtained by measuring an atomic composition according to an embodiment of the present disclosure;

FIG. 3A is an Atomic Force Microscope (AFM) photograph of a surface of a barrier layer in a nitride based semiconductor device without a silicon carbon nitride (SiₓC₁₋ₓN) functional layer according to a comparative example;

FIG. 3B is an AFM photograph of a surface of a barrier layer in a nitride based semiconductor device including a SiₓC₁₋ₓN functional layer according to an embodiment of the present disclosure;

FIG. 4A is a graph illustrating a current-voltage (I-V) property measured using a Transmission Line Measurement (TLM) pattern in a nitride based semiconductor device without a SiₓC₁₋ₓN functional layer according to a comparative example;

FIG. 4B is a graph illustrating an I-V property measured using a TLM pattern in a nitride based semiconductor device including a SiₓC₁₋ₓN functional layer according to an embodiment of the present disclosure;

FIG. 5 is a graph illustrating a forward I-V property measured at a Schottky barrier diode without a SiₓC₁₋ₓN functional layer according to a comparative example, and a forward I-V property measured at a Schottky barrier diode including a SiₓC₁₋ₓN functional layer according to an embodiment of the present disclosure; and

FIG. 6 is a graph illustrating a leakage current property at a Schottky barrier diode without a SiₓC₁₋ₓN functional layer according to a comparative example, and a leakage current property at a Schottky barrier diode including a SiₓC₁₋ₓN functional layer according to an embodiment of the present disclosure.

### DETAILED DESCRIPTION

Reference will now be made in detail to exemplary embodiments of the present disclosure, examples of which are illustrated in the accompanying drawings, wherein like reference numerals refer to like elements throughout. Exemplary embodiments are described below to explain the present disclosure by referring to the figures.

Throughout the specification, when it describes that each of a layer, a side, a chip, and the like is formed “on” or “under” a layer, a side, a chip, and the like, the term “on” may include “directly on” and “indirectly on by interposing another element therebetween,” and the term “under” may include “directly under” and “indirectly under by interposing another element therebetween.” A non-limiting example for “on” or “under” of each element may be determined based on a corresponding drawing.

A size of each element in the drawings may be exaggerated for ease of description, and may not indicate the actual size of the element.

Hereinafter, exemplary embodiments of the present disclosure will be described in detail with reference to the accompanying drawings. However, the present disclosure is not limited to the embodiments described.

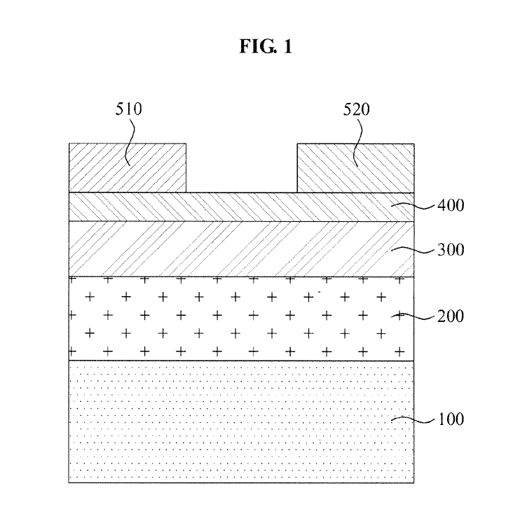

FIG. 1 is a cross-sectional view illustrating a structure of a nitride based semiconductor device according to an embodiment of the present disclosure.

Referring to FIG. 1, the nitride based semiconductor device may include a substrate 100, a nitride semiconductor layer 200 (e.g., gallium nitride (GaN)) formed on the substrate 100, a barrier layer 300 formed on the GaN layer 200 and having a different band-gap energy than the GaN layer 200, and a silicon carbon nitride (SiₓC₁₋ₓN) functional layer 400 formed on the barrier layer 300.

The substrate 100 may be formed of various materials in view of a lattice constant of the GaN layer 200, a thermal expansion coefficient, and the like. The substrate 100 may include an insulating substrate, for example, a glass substrate or a sapphire substrate; or may include a conductive substrate, for example, a silicon (Si) substrate, a silicon carbide (SiC) substrate, or a zinc oxide (ZnO) substrate. In addition, the substrate 100 may include a substrate for growing nitride, for example, an aluminum nitride (AlN) based substrate or a GaN based substrate.

The GaN layer 200 may be formed on the substrate 100. The GaN layer 200 may act as a buffer layer or a channel layer. For example, the GaN layer 200 may act as the buffer layer so that the barrier layer 300 may be grown. Also, the GaN layer 200 may act as the channel layer where a current may flow, since a two-dimensional electron gas (2-DEG) layer may be formed on the GaN layer 200 due to the difference in band-gap energy between the barrier layer 300 and the GaN layer 200.

The barrier layer 300 may be formed on the GaN layer 200. The barrier layer 300 may include at least one layer formed of a material having Formula 1:

Al_{y}In_{z}Ga_{1-y}N, [Formula 1]

where 0.1≦y≦1 and 0≦z≦0.3.

In Formula 1, when the value of y equals 1 and the value of z equals 0, that is, when the barrier layer 300 is AlN, a morphology on a surface of AlN may be excellent. When the value of y is between 0.1 and 1, the morphology on the surface of AlN may vary.

As described above, the barrier layer 300 may include at least one layer formed of a material having a formula that may be expressed as Al_{y}In_{z}Ga_{1-y}N, where 0.1≦y≦1 and 0≦z≦0.3. For example, the barrier layer 300 may be formed of a material having a formula of Al_{y}Ga_{1-y}N, AlN, or AlIn_{z}N, or may be formed of at least two materials having different formulas, for example, Al_{y}Ga_{1-y}N/AlN, AlIn_{z}N/AlN, Al_{y}Ga_{1-y}N/AlIn_{z}N, or the like.

In addition, a layer which includes the material having Formula 1 in which a p-type material is doped may be formed on the barrier layer 300. That is, a p-Al_{y}In_{z}Ga_{1-y}N layer formed by doping the p-type material into a material having a formula of Al_{y}In_{z}Ga_{1-y}N, where 0.1≦y≦1 and 0≦z≦0.3, may be formed on the barrier layer 300. In addition, a low temperature GaN layer may be formed on the barrier layer 300. The p-Al_{y}In_{z}Ga_{1-y}N layer and the low temperature GaN layer may be used to protect a surface of the barrier layer 300.

The SiₓC₁₋ₓN functional layer 400, where 0≦x≦1, may be formed on the barrier layer 300. In the SiₓC₁₋ₓN functional layer 400, silicon (Si) and carbon (C) may be combined in a predetermined ratio, and the ratio of Si and C may be adjusted properly. The SiₓC₁₋ₓN functional layer 400 may improve a surface roughness by protecting a surface of the barrier layer 300, and may block a surface leakage current of the barrier layer 300.

SiₓC₁₋ₓN in the SiₓC₁₋ₓN functional layer 400 may be manufactured using a material having various crystalline phases for blocking the surface leakage current of the barrier layer 300, and enabling a smooth current flow between the barrier layer 300 and an ohmic metal, or the like. For example, the SiₓC₁₋ₓN in the SiₓC₁₋ₓN functional layer 400 may be manufactured using at least one of a single crystal, a poly crystal, and an amorphous SiₓC₁₋ₓN.

In the nitride based semiconductor device, the SiₓC₁₋ₓN functional layer 400 may have a thickness in a range of about 0.1 nanometers (nm) to 100 nm.

According to an embodiment of the present disclosure, by forming a SiₓC₁₋ₓN functional layer on a barrier layer, a nitride based semiconductor device may improve a surface roughness of the barrier layer, and may reduce a surface leakage current by, for example, inhibiting aluminum (Al) and oxygen (O) from combining with each other on a surface of the barrier layer.

Also, in comparison to a structure in which the barrier layer and an electrode directly contact each other, a barrier in a structure in which a SiₓC₁₋ₓN functional layer is formed between the barrier layer and an electrode may be relatively low. Accordingly, an operating voltage may be lowered to increase a current density. This operation will be described in detail with reference to the accompanying drawings.

The nitride based semiconductor device according to an aspect of the present disclosure may be applied to various types of electronic devices. That is, although it has been described that the nitride based semiconductor device may be applied to a Schottky barrier diode in the descriptions provided with reference to FIG. 1, application of the nitride based semiconductor device is not limited thereto. For example, the nitride based semiconductor device may be applied to any one of a normally-on device, a normally-off device, and a Schottky barrier diode.

In the exemplary embodiment illustrated in FIG. 1, when the nitride based semiconductor device corresponds to a Schottky barrier diode, an ohmic electrode 510 may be formed of at least one of chromium (Cr), Al, tantalum (Ta), titanium (Ti), gold (Au), nickel (Ni), and platinum (Pt). A Schottky electrode 520 may be formed of at least one of Ni, Au, copper indium oxide (CuInO₂), indium tin oxide (ITO), and Pt, and alloys thereof. Exemplary alloys may include, for example, an alloy of Ni and Au, an alloy of CuInO₂ and Au, an alloy of ITO and Au, an alloy of Ni, Pt, and Au, and an alloy of Pt and Au, but the alloys are not limited thereto.

Herein, an exemplary method of manufacturing a nitride based semiconductor device according to an embodiment of the present disclosure will be described.

A method of manufacturing the nitride based semiconductor device may include forming the GaN layer 200 on the substrate 100, forming, on the GaN layer 200, the barrier layer 300 having a different band-gap energy than the GaN layer 200, and forming the SiₓC₁₋ₓ N functional layer 400 on the barrier layer 300.

The GaN layer 200 may be formed on the substrate 100. The GaN layer 200 may be formed using various methods such as, for example, metal organic chemical vapor deposition (MOCVD), molecular beam epitaxy (MBE), hydride vapor phase epitaxy (HYPE), and the like, but the methods are not limited thereto.

The barrier layer 300 may be formed on the GaN layer 200. The barrier layer 300 may include at least one layer formed of a material having Formula 1:

Al_{y}In_{z}Ga_{1-y}N, [Formula 1]

where 0.1≦y≦1 and 0≦z≦0.3.

That is, the barrier layer 300 may include at least one layer formed of a material having a formula that may be expressed as Al_{y}In_{z}Ga_{1-y}N, where 0.1≦y≦1 and 0≦z≦0.3. For example, the barrier layer 300 may be formed of a material having a formula of Al_{y}Ga_{1-y} N, AlN, or AlIn_{z}N, or may be formed of at least two materials having different formulas, for example, Al_{y}Ga_{1-y}N/AlN, AlIn_{z}N/AlN, Al_{y}Ga_{1-y}N/AlIn_{z}N, or the like.

In addition, a layer in which the material having Formula 1 is doped with a p-type material (i.e., a p-Al_{y}In_{z}Ga_{1-y}N layer), or a low temperature GaN layer, may be formed on the barrier layer 300. The p-Al_{y}In_{z}Ga_{1-y}N layer and the low temperature GaN layer may be used to protect a surface of the barrier layer 300.

The SiₓC₁₋ₓN functional layer 400 may be formed on the barrier layer 300 by various deposition methods including, but not limited to, plasma enhanced chemical vapor deposition (PECVD), and the like. According to an aspect of the present disclosure, the SiₓC₁₋ₓN functional layer 400 may be formed through an in-situ process by MOCVD.

In forming the SiₓC₁₋ₓN functional layer 400 by MOCVD, tetrabromomethane (CBr₄) may be used as a source of C, ditertiarybutyl silane (DTBSI) may be used as a source of Si, and ammonia (NH₃) may be used as a source of nitrogen (N). The SiₓC₁₋ₓN functional layer 400 may be formed through an in-situ process after the barrier layer 300 is formed by MOCVD. Thus, a manufacturing efficiency of the nitride based semiconductor device may be increased.

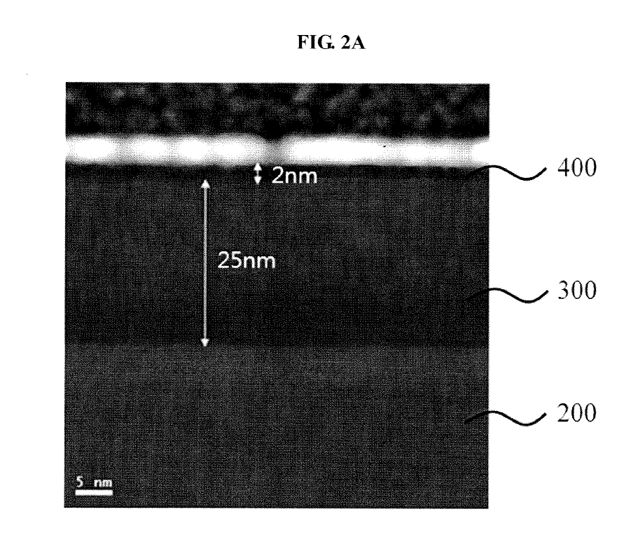

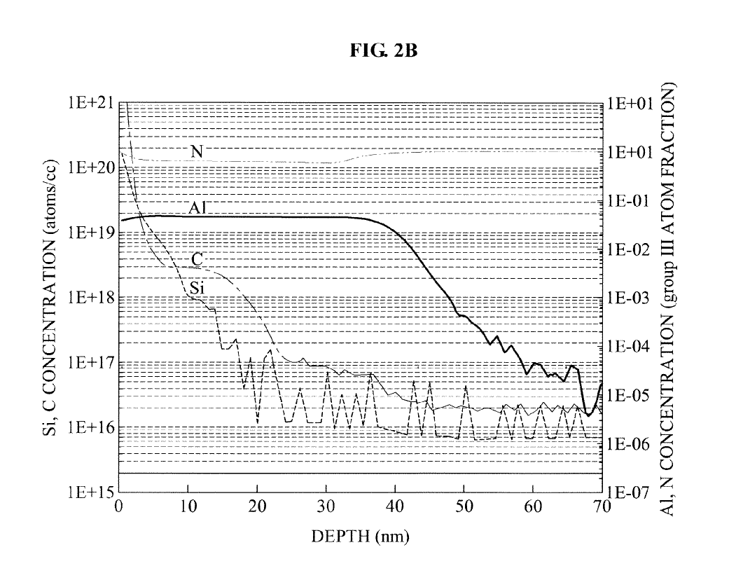

Hereinafter, properties of a nitride based semiconductor device including a SiₓC₁₋ₓN functional layer generated according to an embodiment of the present disclosure will be described in detail with reference to FIGS. 2 through 6, by comparing the properties of the nitride based semiconductor device according to an embodiment of the present disclosure with properties of a nitride based semiconductor device without a SiₓC₁₋ₓN functional layer according to a comparative example.

FIG. 2A is a Transmission Electron Microscope (TEM) photograph of a portion of a nitride based semiconductor device according to an embodiment of the present disclosure. FIG. 2B is a graph illustrating data obtained by measuring an atomic composition at a depth ranging up to about 70 nm through Secondary Ion Mass Spectrometry (SIMS) according to an embodiment of the present disclosure.

As shown in FIG. 2A, it can be seen that a SiₓC₁₋ₓN functional layer 400 was grown to a thickness of about 2 nm on a barrier layer 300 having a thickness of about 25 nm. As shown in FIG. 2B, Si, C, and N were verified as compositions of the SiₓC₁₋ₓN functional layer, and Al was verified as a composition of the barrier layer.

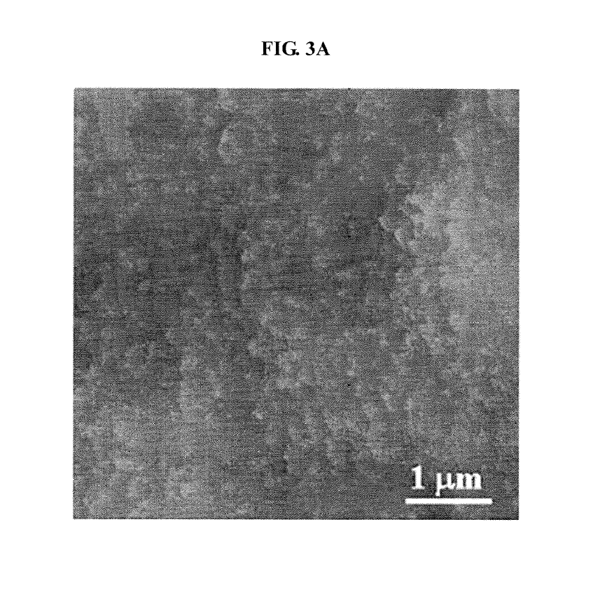

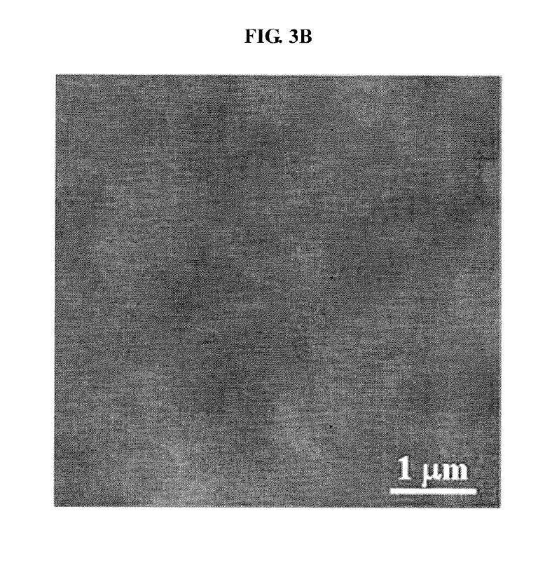

FIG. 3A is an Atomic Force Microscope (AFM) photograph of a surface of a barrier layer in a nitride based semiconductor device without a SiₓC₁₋ₓN functional layer according to a comparative example. FIG. 3B is an AFM photograph of a surface of a barrier layer in a nitride based semiconductor device including a SiₓC₁₋ₓN functional layer according to an embodiment of the present disclosure.

As shown in FIG. 3A, when a SiₓC₁₋ₓN functional layer was not included, a surface roughness of the barrier layer was about 0.7 nm. As shown in FIG. 3B, when the SiₓC₁₋ₓN functional layer was included, the surface roughness of the barrier layer was about 0.44 nm. Accordingly, it can be seen that the surface roughness decreased when the SiₓC₁₋ₓN functional layer was included. When the surface roughness of the barrier layer is reduced, a charge on a surface of the barrier layer may be protected.

Also, when the SiₓC₁₋ₓN functional layer was not included, a 2-DEG mobility measured by a Hall measurement was about 1500 centimeters squared per volt-second (cm²/Vs), and a sheet carrier density was about 8×10¹² per square centimeter (/cm²). On the other hand, when the SiₓC₁₋ₓN functional layer of about 2 nm thickness was included, the 2-DEG mobility decreased to about 1300 cm²/Vs, and the sheet carrier density increased to about 1×10¹³/cm². That is, when the SiₓC₁₋ₓN functional layer is included, the 2-DEG mobility may be reduced since a greater number of electrons may exist on the surface of the barrier layer with improved crystallinity, and thus, scattering may be readily performed.

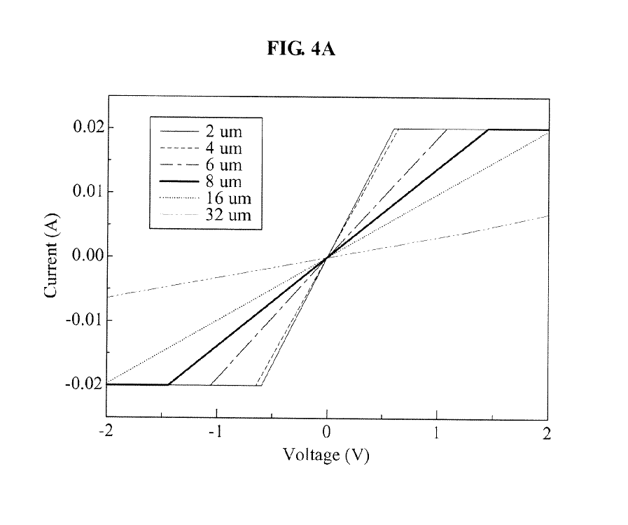

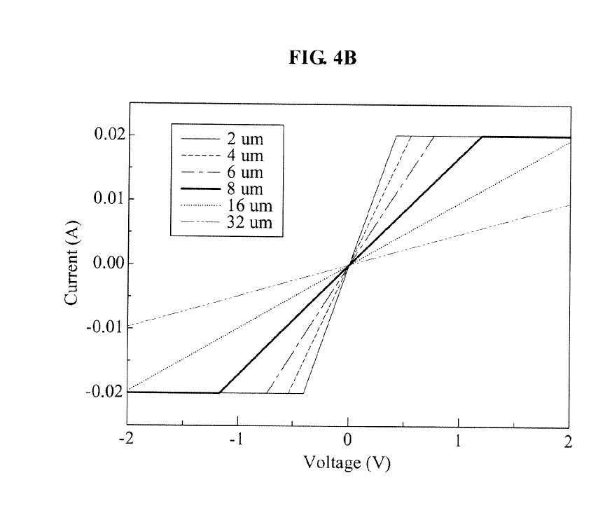

FIG. 4A is a graph illustrating a current-voltage (I-V) property measured using a Transmission Line Measurement (TLM) pattern in a nitride based semiconductor device without a SiₓC₁₋ₓN functional layer according to a comparative example. FIG. 4B is a graph illustrating an I-V property measured using a TLM pattern in a nitride based semiconductor device including a SiₓC₁₋ₓN functional layer according to an embodiment of the present disclosure.

The I-V property graphs of FIGS. 4A and 4B indicate I-V property values that were measured after performing a heat treatment on an ohmic electrode and a Schottky electrode formed on a surface of a barrier layer, at a temperature of 900° C. for a period of 30 seconds. As shown in the graph of FIG. 4A, in the nitride based semiconductor device without the SiₓC₁₋ₓN functional layer according to a comparative example, an ohmic resistance was about 6×10⁻⁵ ohm square centimeters (Ωcm²). As shown in the graph of FIG. 4B, in the nitride based semiconductor device including the SiₓC₁₋ₓN functional layer according to an embodiment of the present disclosure, the ohmic resistance was about 2×10⁻⁵ Ωcm², which is a decrease of about ⅓ of the value in the comparative example.

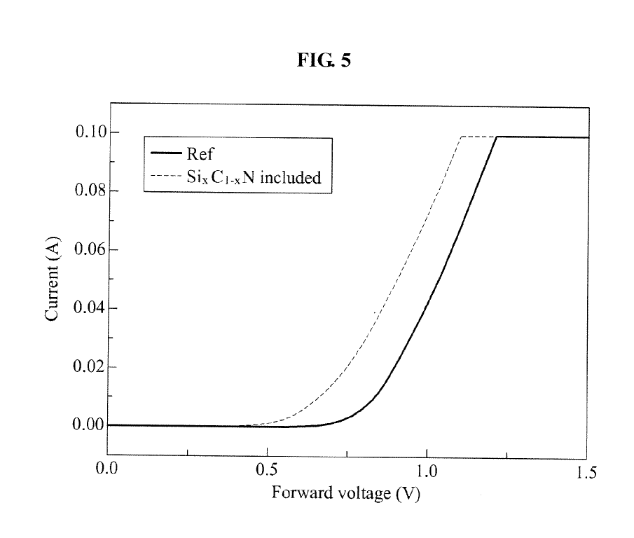

FIG. 5 is a graph illustrating a forward I-V property measured in a Schottky barrier diode without a SiₓC₁₋ₓN functional layer according to a comparative example, and a forward I-V property measured in a Schottky barrier diode including a SiₓC₁₋ₓN functional layer according to an embodiment of the present disclosure.

In the graph of FIG. 5, the line corresponding to Ref indicates a forward I-V property measured in a Schottky barrier diode without the SiₓC₁₋ₓN functional layer according to a comparative example, and the line corresponding to a case in which the SiₓC₁₋ₓN functional layer is included indicates a forward I-V property measured in a Schottky barrier diode including the SiₓC₁₋ₓN functional layer according to an embodiment of the present disclosure.

As shown in the graph of FIG. 5, in the Schottky barrier diode according to an embodiment of the present disclosure, a Schottky barrier height may be lowered due to the existence of the SiₓC₁₋ₓN functional layer. Accordingly, an operating voltage may decrease by 0.2 volts (V) and a higher current density may be obtained at an identical voltage, when compared to Ref corresponding to the comparative example.

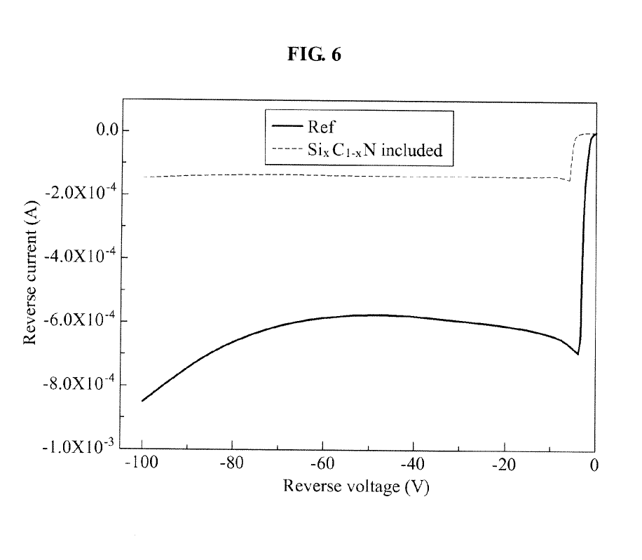

FIG. 6 is a graph illustrating a leakage current property at a Schottky barrier diode without a SiₓC₁₋ₓN functional layer according to a comparative example, and a leakage current property at a Schottky barrier diode including a SiₓC₁₋ₓN functional layer according to an embodiment of the present disclosure.

In the graph of FIG. 6, the line corresponding to Ref indicates a Schottky barrier diode without the SiₓC₁₋ₓN functional layer according to a comparative example, and the line corresponding to a case in which the SiₓC₁₋ₓN functional layer is included indicates a Schottky barrier diode including the SiₓC₁₋ₓN functional layer according to an embodiment of the present disclosure.

When the SiₓC₁₋ₓN functional layer is included, a surface roughness of the barrier layer may be relatively low, and the SiₓC₁₋ₓN functional layer may prevent Al and O from combining with each other on a surface of the barrier layer, whereby a leakage current may decrease to be ⅛ of the value in the comparative example as shown in FIG. 6.

According to an embodiment of the present disclosure, by forming a SiₓC₁₋ₓN functional layer on a barrier layer, a nitride based semiconductor device may improve a surface roughness of the barrier layer, and may reduce a surface leakage current by, for example, inhibiting Al and O from combining with each other on the barrier layer.

Also, when compared to a structure in which a barrier layer and an electrode directly contact each other, a barrier may be relatively low in a structure in which a SiₓC₁₋ₓN functional layer is formed between the barrier layer and the electrode. Accordingly, an operating voltage may be lowered to increase a current density.

According to another embodiment of the present disclosure, in an exemplary method of manufacturing a nitride based semiconductor device, a surface roughness of a barrier layer may be improved by employing an in-situ process by MOCVD to form a SiₓC₁₋ₓN functional layer, and by growing the SiₓC₁₋ₓN functional layer using CBr₄ as a source of C, DTBSI as a source of Si, and NH₃ as a source of N.

Although a few exemplary embodiments of the present disclosure have been shown and described, the present disclosure is not limited to the described exemplary embodiments. Instead, it would be appreciated by those having ordinary skill in the art that changes may be made to these exemplary embodiments without departing from the principles and spirit of the disclosure, the scope of which is defined by the claims and their equivalents.

What is claimed is:

1. A nitride based semiconductor device, comprising:
a substrate;
a gallium nitride (GaN) layer formed on the substrate;
a barrier layer formed on the GaN layer, the barrier layer having a different band-gap energy than the GaN layer; and
a silicon carbon nitride (SiₓC₁₋ₓN) functional layer formed on the barrier layer.

2. The nitride based semiconductor device of claim 1, wherein x in the SiₓC₁₋ₓN functional layer has a value in a range of 0≦x≦1.

3. The nitride based semiconductor device of claim 1, wherein the SiₓC₁₋ₓN in the SiₓC₁₋ₓN functional layer corresponds to at least one of a single crystal, a poly crystal, and an amorphous SiₓC₁₋ₓN.

4. The nitride based semiconductor device of claim 1, wherein the SiₓC₁₋ₓN functional layer has a thickness in a range from 0.1 nanometers (nm) to 100 nm.

5. The nitride based semiconductor device of claim 1, wherein
the barrier layer comprises at least one layer formed of a material having Formula 1:
Al_{y}In_{z}Ga_{1-y}N, [Formula 1]
where 0.1≦y≦1 and 0≦z≦0.3.

6. The nitride based semiconductor device of claim 1, further including a low temperature GaN layer formed on the barrier layer.

7. The nitride based semiconductor device of claim 1, wherein the substrate is found of a material selected from a group consisting of sapphire, silicon, aluminum nitride (AlN), silicon carbide (SiC), and GaN.

8. The nitride based semiconductor device of claim 1, wherein the nitride based semiconductor device is selected from a group consisting of a normally-on device, a normally-off device, and a Schottky barrier diode.

9. The nitride based semiconductor device of claim 8, wherein an ohmic electrode in the Schottky barrier diode is formed of a material selected from a group consisting of chromium (Cr), aluminum (Al), tantalum (Ta), titanium (Ti), gold (Au), nickel (Ni), and platinum (Pt).

10. The nitride based semiconductor device of claim 8, wherein a Schottky electrode in the Schottky barrier diode is formed of a material selected from a group consisting of Ni, Au, copper indium oxide (CuInO₂), indium tin oxide (ITO), and Pt, and alloys thereof.

11. A method of manufacturing a nitride based semiconductor device, the method comprising:
forming a gallium nitride (GaN) layer on a substrate;
forming, on the GaN layer, a barrier layer having a different band-gap energy than the GaN layer; and
forming a silicon carbon nitride (SiₓC₁₋ₓN) functional layer on the barrier layer.

12. The method of claim 11, wherein tetrabromomethane (CBr₄) is used as a source of carbon (C), ditertiarybutyl silane (DTBSI) is used as a source of silicon (Si), and ammonia (NH₃) is used as a source of nitrogen (N), in the forming of the SiₓC₁₋ₓN functional layer.

13. The method of claim 11, wherein the SiₓC₁₋ₓN functional layer is formed through an in-situ process by metal organic chemical vapor deposition (MOCVD).

14. The method of claim 11, wherein x in the SiₓC₁₋ₓN functional layer has a value in a range of 0≦x≦1.

15. The method of claim 11, wherein the SiₓC₁₋ₓN in the SiₓC₁₋ₓN functional layer corresponds to at least one of a single crystal, a poly crystal, and an amorphous SiₓC₁₋ₓN.

16. The method of claim 11, wherein the SiₓC₁₋ₓN functional layer has a thickness in a range from 0.1 nanometers (nm) to 100 nm.

17. The method of claim 11, wherein
the barrier layer comprises at least one layer formed of a material having Formula 1:
Al_{y}In_{z}Ga_{1-y}N, [Formula 1]
where 0.1≦y≦1 and 0≦z≦0.3.

18. A nitride based semiconductor device, comprising:
a substrate;
a nitride semiconductor layer formed on the substrate;
a barrier layer formed on the nitride semiconductor layer, the barrier layer having a different band-gap energy than the nitride semiconductor layer; and
a silicon carbon nitride (SiₓC₁₋ₓN) functional layer formed on the barrier layer.

19. The nitride based semiconductor device of claim 18, wherein x in the SiₓC₁₋ₓN functional layer has a value in a range of 0≦x≦1.

20. The nitride based semiconductor device of claim 18, further including at least one of a low temperature GaN layer and a p-type nitride semiconductor layer formed on the barrier layer.

21. The nitride based semiconductor device of claim 20, wherein the SiₓC₁₋ₓN functional layer is formed on the at least one of a low temperature GaN layer and a p-type nitride semiconductor layer.

22. The nitride based semiconductor device of claim 18, wherein the SiₓC₁₋ₓN functional layer is formed directly on the barrier layer.
